(19) United States
(12) Patent Application Publication
(10) Pub. No.: US 2008/0277663 A1
(43) Pub. Date: Nov. 13, 2008

(54) Thin film transistor and method of manufacturing the same

(75) Inventors: Dong-hun Kang, Yongin-si (KR); I-hun Song, Seongnam-si (KR); Elvira Fortunato, Caparica (PT); Rodrigo Martins, Caparica (PT)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/984,072

(22) Filed: Nov. 13, 2007

(30) Foreign Application Priority Data
May 8, 2007 (KR) 10-2007-0044721

(51) Int. Cl. H01L 29/10; H01L 21/84

(52) U.S. Cl. 257/57; 438/151; 257/E29.043; 257/E21.703

(57) ABSTRACT

Provided is a thin film transistor that includes a substrate on which an insulating layer is formed, a gate formed on a region of the insulating layer, a gate insulating layer formed on the insulating layer and the gate, a channel region formed on the gate insulating layer on a region corresponding to the location of the gate, a source and a drain respectively formed by contacting either side of the channel region; and a passivation layer formed of a compound made of a group II element and a halogen element on the channel region.

### CROSS-REFERENCE TO RELATED PATENT APPLICATION

This application claims the benefit of Korean Patent Application No. 10-2007-0044721, filed on May 8, 2007, in the Korean Intellectual Property Office, the disclosure of which is incorporated herein in its entirety by reference.

### BACKGROUND OF THE INVENTION

1. Field of the Invention

The present invention relates to a thin film transistor, and more particularly, to a thin film transistor in which a passivation layer that includes a group II element and a halogen group element is formed on a channel region, and a method of manufacturing the thin film transistor.

2. Description of the Related Art

As the demand for high integrity semiconductor device increases, the structure of a unit cell of the semiconductor device becomes more complicated, i.e., a three dimensional structure, and thus, more factors that limit the structure of the semiconductor device present. In the case of a thin film transistor used in various fields, the manufacturing process must be simple and the threshold voltage characteristic must be reliable.

FIG. 1A is a cross-sectional view of the structure of a conventional bottom gate type thin film transistor. Referring to FIG. 1A, an insulating layer 12 is formed on a substrate 11 formed of, for example, silicon, and a gate 13 is formed on a region of the insulating layer 12. A gate insulating layer 14 is formed on the insulating layer 12 and the gate 13, and a channel region 15 is formed on a region of the gate insulating layer 14 corresponding to the location of the gate 13. A source 16a and a drain 16b respectively are formed on either side of the gate insulating layer 14 and the channel region 15. A passivation layer 17 for protecting the channel region 15 is formed on the passivation layer 17 using a passivation process.

In a conventional thin film transistor, the passivation layer 17 is generally formed of oxides or nitrides in the passivation process. However, if the passivation layer 17 is formed of oxides or nitrides, the annealing temperature is as high as approximately 350° C., and the high temperature adversely affects the characteristics of a semiconductor layer, for example, the channel region 15 under the passivation layer 17.

FIG. 1B is a graph showing drain current Ids vs. gate voltage Vg of a conventional thin film transistor. The line BP (before passivation) indicates the drain current Ids vs. gate voltage Vg in the case of a thin film transistor sample in which a source 16a and a drain 16b are formed on either side of the channel region 15 without performing a passivation process, and the line AP (after passivation) indicates the drain current Ids vs. gate voltage Vg in the case of a thin film transistor specimen in which SiO₂ is deposited on the channel region 15 by a passivation process. Referring to FIG. 1B, it is seen that the passivation process, by which an oxide is coated on the channel region 15, greatly affects the I-V characteristics of a device. After the passivation process, a high temperature heat treatment process is required, which also adversely affects the device characteristics. Therefore, a reliable thin film transistor can hardly be manufactured by changing the threshold voltage of the thin film transistor.

### SUMMARY OF THE INVENTION

To address the above and/or other problems, the present invention provides a thin film transistor in which a passivation layer is formed of a material that does not affect a semiconductor layer under the passivation layer, has stable characteristics, and can be treated at a low temperature.

According to an aspect of the present invention, there is provided a thin film transistor comprising: a substrate on which an insulating layer is formed; a gate formed on a region of the insulating layer; a gate insulating layer formed on the insulating layer and the gate; a channel region formed on the gate insulating layer on a region corresponding to the location of the gate; source and drain respectively formed by contacting either side of the channel region; and a passivation layer formed of a compound made of a group II element and a halogen element on the channel region.

The passivation layer may be formed to a single layer of a compound made of a group II element and a halogen element or a multilayer structure by further forming a layer formed of SiO₂, Si₃N₄, HfO₂, Al₂O₃, or ZrO₂ on the compound made of a group II element and a halogen element.

The passivation layer may have a thickness of 50 to 300 nm.

The channel region may be formed of a compound made by adding a metal such as Ga, In, Sn, Ti, or Al to ZnO.

The channel region may be formed of Ga₂O₃, In₂O₃, and ZnO.

The source and drain may be formed of a metal or a conductive oxide.

The source and drain may be formed of a metal selected from the group consisting of Ti, Pt, Mo, Al, W, and Cu or a conductive oxide selected from the group consisting of IZO, AZO, and GZO.

According to an aspect of the present invention, there is provided a method of manufacturing a thin film transistor, comprising: forming an insulating layer on a substrate, and forming a gate on the insulating layer; forming a gate insulating layer on the gate, and forming a channel region on a region of the gate insulating layer corresponding to the gate; forming a source and a drain on either side of the channel region and the gate insulating layer; and forming a passivation layer using a compound made of a group II element and a halogen element.

After forming of the passivation layer using a compound made of a group II element and a halogen element, the passivation layer may be formed to a multiple layer structure by further forming a layer of SiO₂, Si₃N₄, HfO₂, Al₂O₃, or ZrO₂ on the compound made of a group II element and a halogen element.

The method may further comprise, after forming of the passivation layer, annealing the thin film transistor at a temperature in a range from room temperature to 300° C.

The passivation layer may be formed to a thickness of 50 to 300 nm.

The passivation layer may be formed by an evaporation process, an E-beam process, or a sputtering process.

### BRIEF DESCRIPTION OF THE DRAWINGS

The above and other features and advantages of the present invention will become more apparent by describing in detail exemplary embodiments thereof with reference to the attached drawings in which:

FIG. 1A is a cross-sectional view of a conventional thin film transistor;

FIG. 1B is a graph showing I-V characteristics of a conventional thin film transistor having a passivation layer;

FIG. 2 is a cross-sectional view of a thin film transistor according to an embodiment of the present invention;

FIGS. 3A through 3G are cross-sectional views illustrating a method of manufacturing a thin film transistor according to an embodiment of the present invention; and

FIG. 4 is a graph showing I-V characteristics of a thin film transistor according to an embodiment of the present invention.

### DETAILED DESCRIPTION OF THE INVENTION

The present invention will now be described more fully with reference to the accompanying drawings in which exemplary embodiments of the invention are shown. In the drawings, the thicknesses of layers and regions are exaggerated for clarity.

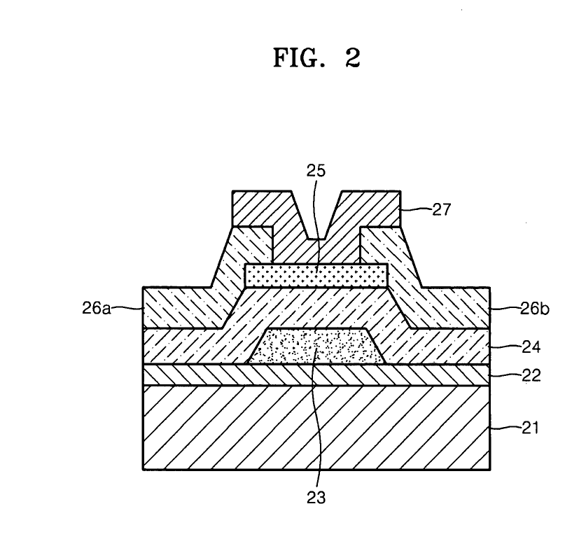

FIG. 2 is a cross-sectional view of a thin film transistor according to an embodiment of the present invention. The thin film transistor of FIG. 2 is a bottom gate type thin film transistor.

Referring to FIG. 2, an insulating layer 22 is formed on a substrate 21, and a gate 23 is formed on a region of the insulating layer 22. A gate insulating layer 24 is formed on the insulating layer 22 and the gate 23, and a channel region 25 is formed on a region of the gate insulating layer 24 corresponding to the location of the gate 23. A source 26a and a drain 26b are formed on either side of a portion of the channel region 25. A passivation layer 27 is formed on the channel region 25.

Materials for forming the layers of the thin film transistor of FIG. 2 will now be described. The substrate 21 can be a conventional substrate used in semiconductor devices, for example, a silicon substrate glass or organic compounds etc. The insulating layer 22 can be, for example, a silicon oxide which is a thermally oxidized silicon substrate, and can be formed to a thickness of approximately 100 nm or less. The gate 23 can be formed of a metal or a conductive metal oxide. The gate insulating layer 24 may be formed of an ordinary insulating material, such as SiO₂ or a high-K material having a dielectric constant higher than that of SiO₂. For example, the gate insulating layer 24 can be formed of Si₃N₄, Al₂O₃ or HfO₂ to a thickness of approximately 200 nm or less. The channel region 25 is formed of a compound thin film, in which a metal such as Ga, In, Sn, Ti, or Al is added to ZnO, to a thickness of 20 to 200 nm. The source 26a and the drain 26b can be formed of a metal such as Ti, Pt, Mo, Al, W, or Cu or a conductive oxide such as indium tin oxide (ITO), indium zinc oxide (IZO) (InZnO), aluminum zinc oxide (AZO) (AlZnO), or gallium zinc oxide (GZO) (GaZnO) to a thickness of approximately 100 nm or less.

The passivation layer 27 may include a material that includes a compound of a group II element and a halogen element and has a chemical equation of XY₂. X is a group II element such as Be, Mg, Ca, etc, and Y can be a halogen group element such as Cl, F, Br, I, etc. The passivation layer 27 can be formed to a thickness of 50 to 300 nm. As described above, the passivation layer 27 can be formed as a single layer of a compound of a group II element and a halogen element, or can be formed as a bilayer or a multilayer structure by further forming a layer of SiO₂, Si₃N₄, HfO₂, Al₂O₃, or ZrO₂ on the compound made of a group II element and a halogen element.

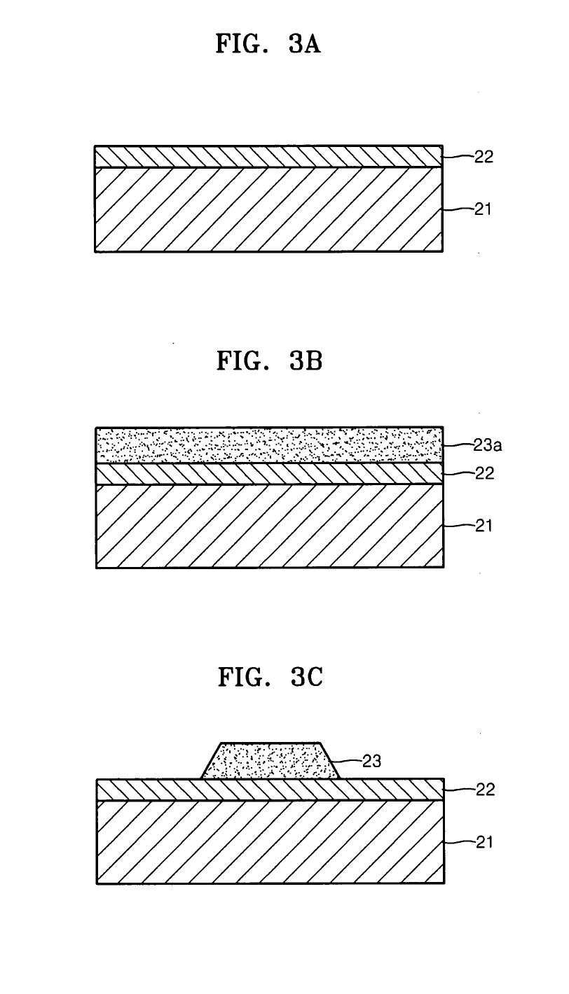

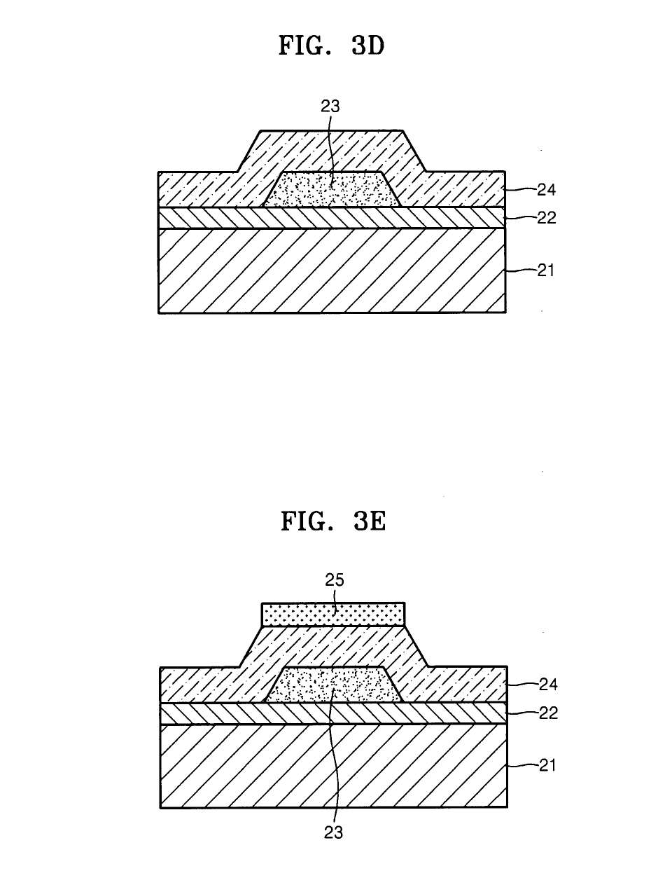

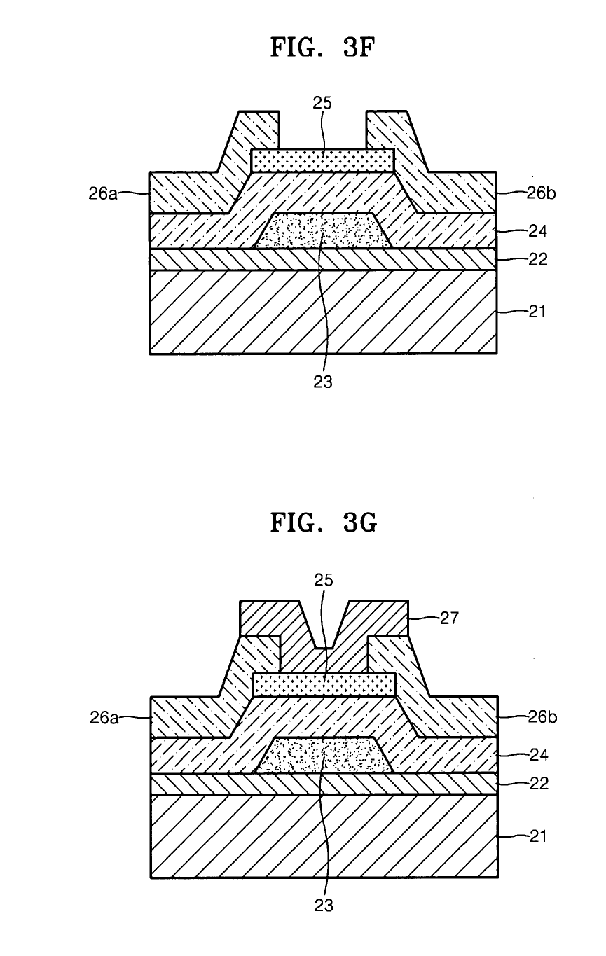

A method of manufacturing a thin film transistor according to an embodiment of the present invention will now be described with reference to FIGS. 3A through 3H.

Referring to FIG. 3A, an insulating layer 22 is formed on a substrate 21. For example, the insulating layer 22 can be a silicon oxide film and can be formed by thermally oxidizing the surface of a silicon substrate.

Referring to FIG. 3B, a conductive material 23a is deposited on the insulating layer 22 using a sputtering process. Referring to FIG. 3C, a gate 23 is formed by patterning the conductive material 23a.

Referring to FIG. 3D, a gate insulating layer 24 is formed on the gate 23 by coating an insulating material such as SiO₂ or Si₃N₄ using a plasma enhanced chemical vapor deposition (PECVD) method.

Referring to 3E, a channel region 25 is formed by patterning a channel material after coating the channel material on the gate insulating layer 24. The channel region 25 may be formed of a compound obtained by adding a metal such as Ga, In, Sn, or Al to ZnO, for example, a compound of Ga₂O₃, In₂O₃, and ZnO. For deposition, the metal compound of Zn and Ga, In, Sn, or Al can be used as a single target for sputtering, or each target of ZnO and a metal of Ga, In, Sn, or Al can be co-sputtered. For example, when a single target is used, a compound formed of Ga₂O₃, In₂O₃, and ZnO in a ratio of 2:2:1 at % can be used. After the channel region 25 is formed, an annealing process can be performed at a temperature of 400° C. to activate the channel region, preferably, at 200 to 300° C. under an N₂ atmosphere. The annealing process can be performed after the source 26a and the drain 26b are formed. The annealing can be performed in a furnace, or by using a rapid thermal annealing (RTA) method, a laser, or a hot plate.

Referring to FIG. 3F, after coating a conductive material on the gate insulating layer 24 and the channel region 25, the source 26a and the drain 26b are formed by patterning the conductive material on the channel region 25.

Referring to FIG. 3G, after coating a passivation material on the channel region 25, a passivation layer 27 is formed using a lift-off process. The passivation layer 27 can also be formed using an evaporation process, an E-beam process, or a sputtering method. The passivation layer 27 can be formed as a single layer of a compound of a group II element and a halogen element, or can be formed as a bilayer structure by further forming a layer of SiO₂, Si₃N₄, HfO₂, Al₂O₃, or ZrO₂ on the compound made of a group II element and a halogen element. After the passivation layer 27 is formed, annealing is performed at a temperature in a range from room temperature to 300° C., and more preferably, from room temperature to 250° C. A thin film transistor according to the present embodiment can be manufactured as described above.

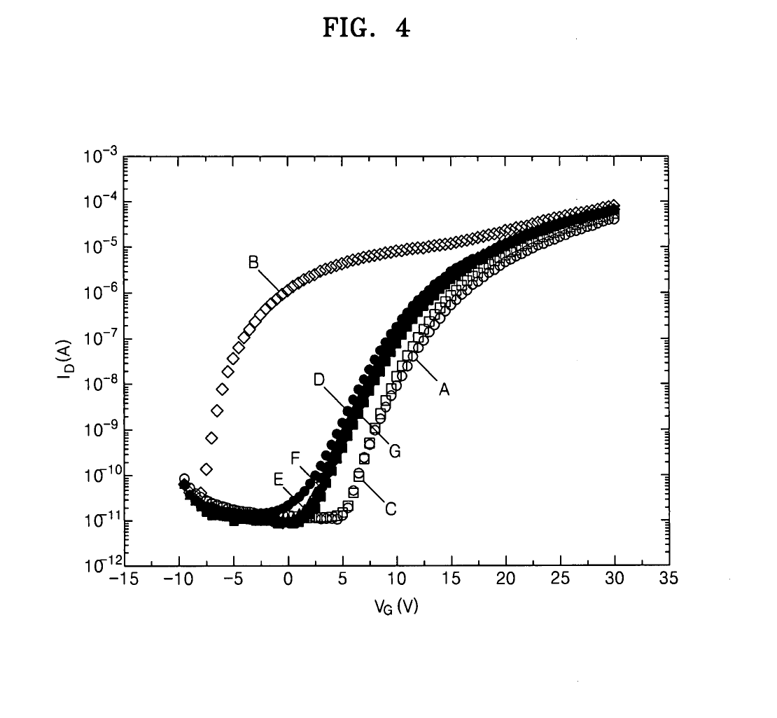

FIG. 4 is a graph showing drain currents I with respect to gate voltages V in a thin film transistor according to an embodiment of the present invention. In each of specimens for this experiment, the substrate 21 is formed of Si, the insulating layer 22 is formed of SiO2, the gate 23 is formed of Mo, the gate insulating layer 24 is formed of Si₃N₄, the channel region 25 is formed of Ga₂O₃, In₂O₃, and ZnO in a ratio of 2:2:1 at %, the source 26a and the drain 26b are formed of IZO (InZnO), and the passivation layer 27 is formed of MgF₂.

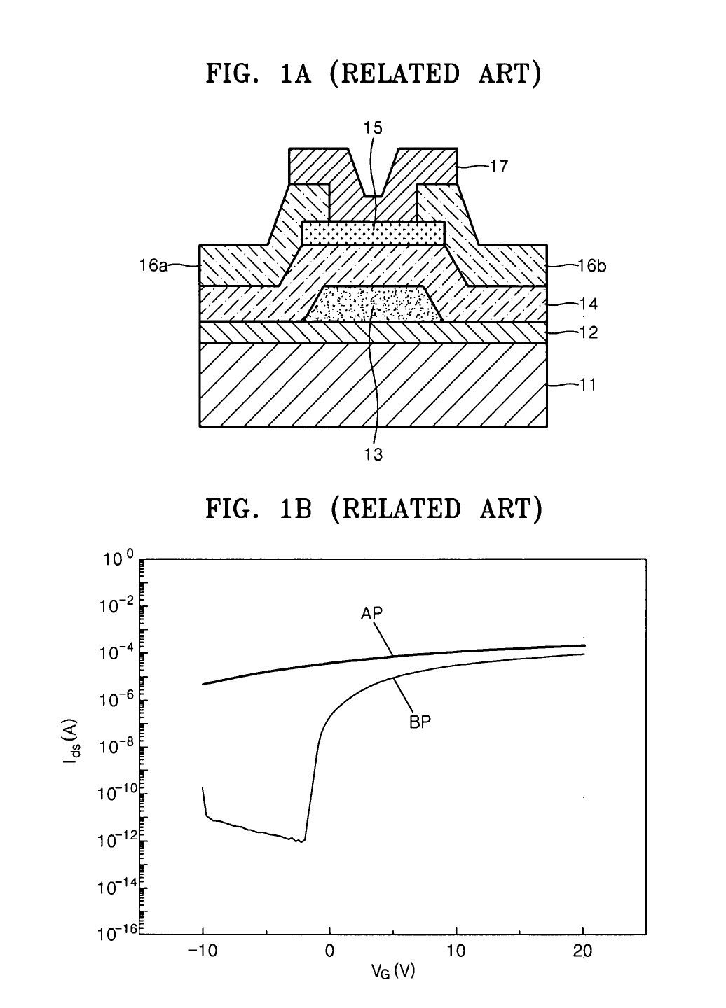

Referring to FIG. 4, curve A indicates the measured I-V characteristics of thin film transistor specimen in which the channel region 25 is formed before the passivation layer 27 is formed and the specimen is annealed at a temperature of 250° C. for approximately 1 hour. Curve B indicates the measured I-V characteristics of the specimen of curve A after the passivation layer 27 is formed. Although curve B is shifted in a direction of −V due to the formation of the passivation layer 27, the shifting magnitude is reduced when compared to the result of FIG. 1B. The measured I-V characteristics of the specimen of curve B in which the passivation layer 27 is formed and for which annealing is performed at temperature of 250° C. is indicated by curve C, and the measured I-V characteristics after a few minutes is indicated by curve D. It is seen that curves C and D have a similar trend to the curve A. Curve E indicates the I-V characteristics of the specimen of curve D after two weeks, and curves F and G respectively indicate measured I-V characteristics after one month and two months. It is seen that the I-V characteristics of the specimen are unchanged after a few months.

That is, when the passivation layer 27 is formed of a compound made of a group II element and a halogen element, the degree of shifting of the I-V curve is reduced compared to a conventional passivation layer formed of an oxide or nitride. Also, it is seen that due to the low temperature annealing, the thin film transistor readily recovers the I-V characteristics to a state where the passivation layer is not formed.

According to the present invention, since a passivation layer, which is essential for manufacturing a thin film transistor, is formed of a compound made of a group II element and a halogen element, a thin film transistor having stable electrical characteristics can be manufactured. Also, a high temperature process is unnecessary, and an annealing process is performed at a relatively low temperature after the passivation layer is formed, such that the characteristic change of a channel region under the passivation layer can be prevented.

While the present invention has been particularly shown and described with reference to embodiments thereof, it should not be construed as being limited to the embodiments set forth herein but as an exemplary. Those who skilled in this art, for example, various electronic device or apparatuses that use a transistor in which a passivation layer is formed of a compound made of a group II element and a halogen element can be manufactured. Therefore, the scope of the invention is defined not by the detailed description of the invention but by the appended claims.

What is claimed is:

1. A thin film transistor comprising:
a substrate on which an insulating layer is formed;
a gate formed on a region of the insulating layer;
a gate insulating layer formed on the insulating layer and the gate;
a channel region formed on the gate insulating layer on a region corresponding to the location of the gate;
a source and a drain respectively formed by contacting either side of the channel region; and
a passivation layer formed of a compound made of a group II element and a halogen element on the channel region.

2. The thin film transistor of claim 1, wherein the passivation layer is formed as a single layer of a compound made of a group II element and a halogen element or as a multilayer structure by further forming a layer formed of SiO₂, Si₃N₄, HfO₂, Al₂O₃, or ZrO₂ on the compound made of a group II element and a halogen element.

3. The thin film transistor of claim 1, wherein the passivation layer has a thickness of 50 to 300 nm.

4. The thin film transistor of claim 1, wherein the channel region is formed of a compound made by adding a metal such as Ga, In, Sn, Ti, or Al to ZnO.

5. The thin film transistor of claim 1, wherein the channel region is formed of Ga₂O₃, In₂O₃, and ZnO.

6. The thin film transistor of claim 1, wherein the source and drain are formed of a metal or a conductive oxide.

7. The thin film transistor of claim 1, wherein the source and drain are formed of a metal selected from the group consisting of Ti, Pt, Mo, Al, W, and Cu or a conductive oxide selected from the group consisting of IZO, AZO, and GZO.

8. A method of manufacturing a thin film transistor, comprising:
forming an insulating layer on a substrate, and forming a gate on the insulating layer;
forming a gate insulating layer on the gate, and forming a channel region on a region of the gate insulating layer corresponding to the gate;
forming source and drain on either side of the channel region; and
forming a passivation layer using a compound made of a group II element and a halogen element.

9. The method of claim 8, wherein, after forming of the passivation layer using a compound made of a group II element and a halogen element, the passivation layer is formed as a multiple layer structure by further forming a layer of SiO₂, Si₃N₄, HfO₂, Al₂O₃, or ZrO₂ on the compound made of a group II element and a halogen element.

10. The method of claim 8, after forming of the passivation layer, further comprising annealing the thin film transistor at a temperature in a range from room temperature to 300° C.

11. The method of claim 8, wherein the passivation layer is formed to a thickness of 50 to 300 nm.

12. The method of claim 8, wherein the passivation layer is formed by an evaporation process, an E-beam process, or a sputtering process.
